(19) United States
(12) Patent Application Publication
(10) Pub. No.: US 2019/0062916 A1
(43) Pub. Date: Feb. 28, 2019

(54) Lanthanide, Yttrium and Scandium precursors for ALD, CVD and Thin Film Doping and Methods of Use

(71) Applicant: Applied Materials, Inc., Santa Clara, CA (US)

(72) Inventors: Benjamin Schmiege, Santa Clara, CA (US); Jeffrey W. Anthis, San Jose, CA (US)

(21) Appl. No.: 16/115,051

(22) Filed: Aug. 28, 2018

Related U.S. Application Data
(60) Provisional application No. 62/552,122, filed on Aug. 30, 2017.

(51) Int. Cl. C23C 16/455; C23C 16/40; C07F 5/00

(52) U.S. Cl. CPC C23C 16/45553; C23C 16/36; C07F 5/003; C23C 16/405

(57) ABSTRACT

Methods for depositing a film comprising exposing a substrate surface to a bis-amidinate metal precursor and a co-reactant to form a metal containing film are described. The bis-amidinate metal precursor comprises a metal atom comprising one or more lanthanide.

### CROSS-REFERENCE TO RELATED APPLICATIONS

This application claims priority to U.S. Provisional Application No. 62/552,122, filed Aug. 30, 2017, the entire disclosure of which is hereby incorporated by reference herein.

### TECHNICAL FIELD

The present disclosure relates generally to methods of depositing films and doping films. In particular, the disclosure relates to methods of depositing or doping films using lanthanide, yttrium and scandium precursors.

### BACKGROUND

The push to engineer smaller and smaller microelectronic devices has opened up an increasing portion of the periodic table. While there is a large amount of research on Ln, Y and Sc inorganic and organometallic compounds, developing new compounds and exploring reactivity, there has been little progress in improving properties for vapor deposition methods. Vapor deposition of yttrium, scandium and lanthanide thin films has primarily focused on metal oxide films. The metal precursors typically suffer from low volatility and a challenging balance to maintain both chemical stability and high enough reactivity with typical deposition co-reactants. The typical precursors also tend to not be very reactive with reagents such as ammonia (NH₃), used to target metal nitride films. There is a need in the art for methods for depositing and doping films using lanthanide, yttrium and scandium precursors.

### SUMMARY

One or more embodiments of the disclosure are directed to processing methods comprising exposing a substrate surface to a bis-amidinate metal precursor and a co-reactant to form a metal containing film. The bis-amidinate metal precursor comprises a metal comprising one or more lanthanide, two amidinate ligands and one or more non-amidinate ligand.

Additional embodiments of the disclosure are directed to processing methods comprising exposing a substrate surface to a bis-amidinate metal precursor and a co-reactant to form a metal containing film. The bis-amidinate metal precursor comprises a compound with the structure

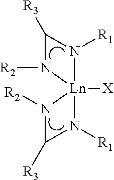

where each of R₁, R₂ and R₃ are independently selected from hydrogen, C1-C8 alkyl, C1-C8 alkenyl, C1-C8 alkynyl, C3-C8 cycloalkyl, dimethylamine, diethylamine, bis(trimethylsilyl)amine or trimethylsilyl groups. The metal atom comprises one or more of La, Ce, Pr, Nd, Pm, Sm, Eu, Gd, Tb, Dy, Ho, Er, Tm, Yb, Lu, Y or Sc. X is a non-amidinate ligand.

Further embodiments of the disclosure are directed to processing methods comprising exposing a substrate surface to a bis-amidinate metal precursor and a co-reactant to form a metal containing film. The bis-amidinate metal precursor comprises a metal atom comprising one or more of La, Ce, Pr, Nd, Pm, Sm, Eu, Gd, Tb, Dy, Ho, Er, Tm, Yb, Lu, Y or Sc. The bis-amidinate metal precursor further comprises at least one non-amidinate ligand selected from the group consisting of allyl, cyclopentadiene, substituted cyclopenadiene, pyridine, substituted pyridine, an RN—CR—CR—NR group, an RN—CR—CR₂ group, a RN—N—NR group, a NR₂ or combinations thereof, where each R is independently H, methyl, ethyl, propyl, isopropyl, butyl, tert-butyl or trimethylsilyl.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure advantageously provide methods of depositing a lanthanide, yttrium or scandium film. Some embodiments advantageously provide chemical vapor deposition (CVD) or atomic layer deposition (ALD) methods to deposit film using precursors with allyl ligands. Some embodiments advantageously provide methods of doping lanthanide, yttrium or scandium based films. Some embodiments advantageously provide methods of doping films with lanthanide, yttrium or scandium.

One or more embodiments of the disclosure are directed to the use of lanthanide, yttrium and scandium compounds containing amidinate ligands for ALD, CVD and semiconductor doping applications. One or more embodiments are directed to processing methods comprising exposing a substrate surface to a metal precursor and a co-reactant to form a metal containing film. The metal precursor comprises a metal atom and two amidinate ligands. The metal atom comprises one or more lanthanide metal.

Some embodiments of the disclosure are directed to the use of lanthanide, yttrium and scandium compounds designed to exhibit enhanced reactivity with metal nitride (or other metal-containing) film vapor deposition co-reagents. In some embodiments, the film precursors have ligands directly bonded to the metal center through M-N bonds.

Embodiments of the disclosure are directed to lanthanide, yttrium and scandium compounds containing two amidinate ligands. As used in this specification and the appended claims, the term “lanthanide” means any element from the lanthanum series: lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu); and the term “lanthanide” also includes yttrium (Y) and scandium (Sc). Lanthanide compounds often exist in the +3 oxidation state; however, those skilled in the art will understand that other oxidation states exist for these elements.

The amidinate ligand—shown in structure (I)—has an N—C—N backbone with R groups on each of the backbone atoms. Without being bound by any particular theory of operation, it is believed that the amidinate ligand coordinates to a metal center through one or both of the nitrogen atoms or through a delocalized backbone. Stated differently, the amidinate ligand has a general formula RNCR′NR″, where each R, R′ and R″ are independently H, a C₁₋₆ alkyl or SiMe₃.

One or more embodiments of the disclosure are directed to processing methods comprising exposing a substrate surface to a bis-amidinate metal precursor and a co-reactant to form a metal containing film. As used in this manner, the term “bis-amidinate” means that the precursor has two amidinate ligands. In some embodiments, the precursor has no more than two and no less than two amidinate ligands. The bis-amidinate metal precursor comprises a metal atom comprising one or more lanthanide, two amidinate ligands and one or more non-amidinate ligand. It will be understood by the skilled artisan that the number of non-amidinate ligands can vary depending on, for example, the oxidation state and charge of the metal complex. In some embodiments, there are no non-amidinate ligands. In some embodiments, there is one non-amidinate ligand. In some embodiments, there are two non-amidinate ligands. In some embodiments, there are three non-amidinate ligands. In some embodiments, there are four non-amidinate ligands.

The bis-amidinate metal precursor of some embodiments comprises a compound according to Structure (I).

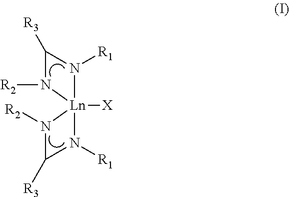

where each of R₁, R₂ and R₃ are independently selected from hydrogen, C1-C8 alkyl, C1-C8 alkenyl, C1-C8 alkynyl, C3-C8 cycloalkyl, dimethylamine, diethylamine, bis(trimethylsilyl)amine or trimethylsilyl groups, and X is a non-amidinate ligand. As used in this specification and the appended claims, the term C followed by a numeral refers to substituent with the specified number of carbon atoms. For example, a C8 alkyl group is an alkyl group with eight carbon atoms. The groups can include hydrogen or other non-carbon atoms as will be understood by the skilled artisan.

In some embodiments, one or more of the two amidinate ligands is a substituted amidinate ligand. The term “substituted amidinate” means that at least one of R₁, R₂ and/or R₃ is not a hydrogen atom. In some embodiments, the substituted amidinate ligand has at least one R group selected from C₁₋₈ alkyl, C₁₋₈ alkenyl, C₁₋₈ alkynyl, branched alkyl, cycloalkyl group, trimethylsilyl, dialkylamine or combinations thereof. In some embodiments, each of the amidinate ligands has the general formula RNCR′NR″, where each R, R′ and R″ is independently H, a C₁₋₆ alkyl or SiMe₃.

Referring back to Structure (I), the X ligand is a non-amidinate ligand. In some embodiments, the non-amidinate ligand primarily bonds to the metal center through a metal-nitrogen bond. In some embodiments, the non-amidinate ligand coordinates to the metal atom through one or more nitrogen atoms so that the bis-amidinate metal precursor has substantially only nitrogen bonding to the metal atom. Those skilled in the art will understand that a metal coordination to a conjugated ligand backbone may include some electrons from non-nitrogen atoms.

Suitable examples of non-amidinate ligands include, but are not limited to,

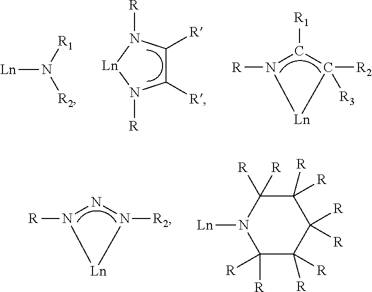

where each R is independently H, methyl, ethyl, propyl, isopropyl, butyl, tert-butyl or trimethylsilyl. In some embodiments, the R groups are non-symmetrical, increasing rotational entropy of the molecule. For example, R₁ and R₂ of the dialkylamine group (—NR₂) may be methyl and t-butyl, respectively. Those skilled in the art will understand that the non-symmetrical substituents are not limited to methyl and t-butyl. In some embodiments, there is at least a two carbon difference between a smaller substituent and a larger substituent in a non-symmetrical ligand.

In some embodiments, the metal precursor comprises at least one neutral ligand. Suitable examples of neutral ligands include, but are not limited to, tetrahydrofuran (THF), water (H₂O), ammonia (NH₃), and carbon monoxide (CO). In some embodiments, the metal precursor is substantially free of neutral ligands. As used in this manner, the term “substantially free of” means that there are less than or equal to about 1% neutral ligands on a molar basis for all substituents.

The metal precursor of some embodiments includes at least one non-amidinate ligand selected from the group consisting of allyl, cyclopentadiene, substituted cyclopenadiene, pyridine, substituted pyridine, an RN—CR—CR—NR group, an RN—CR—CR₂ group, a RN—N—NR group, a NR₂ or combinations thereof.

The allyl ligand is a monoanionic ligand having a three carbon backbone. In organometallic compounds, the negative charge is typically delocalized over the three carbon backbone, as shown in Scheme II. Without being bound by any particular theory of operation, it is believed that each of the carbon atoms may be considered bound to the metal.

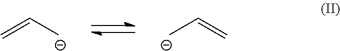

In some embodiments, the metal precursor comprises one or two allyl ligands. The allyl ligand can be un-substituted, having a formula of C₃H₅. In some embodiments, the allyl ligand is substituted at one or more of the carbon atoms. Suitable substituted ally ligands include ligands with C₁₋₆ branched or unbranched alkyl groups (i.e., alkyl groups with one, two, three, four, five or six carbon atoms), C₁₋₆ branched or unbranched alkenyl groups, C₁₋₆ branched or unbranched alkynyl groups, cycloalkyl groups and trimethylsilyl (TMS) groups. In some embodiments, the allyl ligand is substituted at one carbon atom. In some embodiments, the allyl ligand is substituted at two carbon atoms. An exemplary bis-amidinate metal precursor with an allyl ligand is shown in Structure (III).

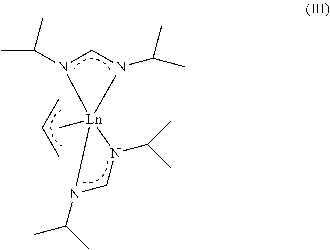

In some embodiments, the non-amidinate ligand of the metal precursor comprises NR₂, where each R is independently a hydrogen, an alkyl, alkenyl, alkynyl or cycloalkyl group. In some embodiments, each R independently has less than or equal to 8 carbons. In some embodiments, the R groups have a difference of at least 2, 3, 4 or 5 carbon atoms.

In some embodiments, the non-amidinate ligand comprises an N—N—N backbone, as shown in Structure (IV). For example, the non-amidinate ligand can have the general formula NR—N—NR, where each R group can be independently selected from hydrogen, C₁₋₈ alkyl, C₁₋₈ alkenyl, C₁₋₈ alkynyl, branched alkyl, cycloalkyl group, trimethylsilyl, dialkylamine or combinations thereof. In some embodiments, each R independently has less than or equal to 8 carbons. In some embodiments, the R groups have a difference of at least 2, 3, 4 or 5 carbon atoms.

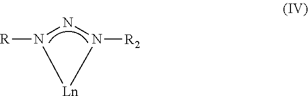

In some embodiments, the non-amidinate ligand comprises a pyridine. As used in this manner, a “pyridine” is a cyclic group having a ring with one nitrogen atom and five carbon atoms, like that shown in Structure (V). A pyridine group is bound or coordinated to the metal center through the nitrogen atom in the ring. Referring to Structure (V), each R group can be independently selected from hydrogen, C₁₋₃ alkyl, C₁₋₈ alkenyl, C₁₋₈ alkynyl, branched alkyl, cycloalkyl group, trimethylsilyl, dialkylamine or combinations thereof. In some embodiments, each R independently has less than or equal to 8 carbons. In some embodiments, at least two R groups have a difference of at least 2, 3, 4 or 5 carbon atoms.

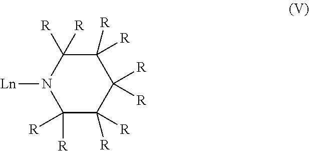

In some embodiments, the non-amidinate ligand comprises a compound with a NR—CR—CR—NR backbone, like that shown in Structure (VI). Each R group can be independently selected from hydrogen, C₁₋₈ alkyl, C₁₋₈ alkenyl, C₁₋₈ alkynyl, branched alkyl, cycloalkyl group, trimethylsilyl, dialkylamine or combinations thereof. In some embodiments, each R independently has less than or equal to 8 carbons. In some embodiments, at least two R groups have a difference of at least 2, 3, 4 or 5 carbon atoms.

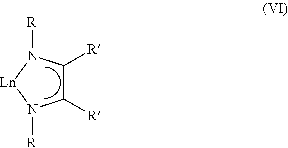

In some embodiments, the non-amidinate ligand comprises a compound with a NR—CR—CR₂ backbone, like that shown in Structure (VII). Each R group can be independently selected from hydrogen, C₁₋₈ alkyl, C₁₋₈ alkenyl, C₁₋₈ alkynyl, branched alkyl, cycloalkyl group, trimethylsilyl, dialkylamine or combinations thereof. In some embodiments, each R independently has less than or equal to 8 carbons. In some embodiments, at least two R groups have a difference of at least 2, 3, 4 or 5 carbon atoms.

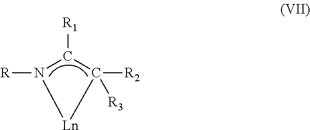

In some embodiments, the non-amidinate ligand of the metal precursor comprises a cyclopentadienyl ligand. The cyclopentadienyl ligand of one or more embodiments has the general formula C₅R₅, where each R is independently H, C₁₋₆ alkyl or SiMe₃. In some embodiments, the cyclopentadienyl ligand comprises C₅Me₅. In one or more embodiments, the cyclopentadienyl ligand comprises C₅Me₄H. In some embodiments, the cyclopentadienyl ligand comprises C₅Me₄SiMe₃.

The metal precursor can be reacted with oxidizing co-reactants such as H₂O, O₂, O₃, oxygen plasma, H₂O₂, NO or NO₂ to form a metal oxide film. As used in this regard, a “metal oxide” film comprises metal atom and oxygen atoms. A metal oxide film can be non-stoichiometric. A film “consisting essentially of” metal oxide has greater than or equal to about 95, 96, 97, 98 or 99 atomic percent metal and oxygen atoms.

In some embodiments, the co-reactant comprises one or more of NO, NO₂, NH₃, N₂H₂ or plasma thereof and the metal containing film comprises a metal nitride. As used in this regard, a “metal nitride” film comprises metal atoms and nitrogen atoms. A metal nitride film can be non-stoichiometric. A film “consisting essentially of” metal nitride has greater than or equal to about 95, 96, 97, 98 or 99 atomic percent metal and nitrogen atoms.

In some embodiments, the co-reactant comprises an organic species and the film comprises a metal carbide. Suitable organic species include, but are not limited to, propylene and acetylene. As used in this regard, a “metal carbide” film comprises metal atoms and carbon atoms. A metal carbide film can be non-stoichiometric. A film “consisting essentially of” metal carbide has greater than or equal to about 95, 96, 97, 98 or 99 atomic percent metal and carbon atoms.

In some embodiments, the metal containing film deposited comprises one or more of a metal carbide (MC), metal oxide (MO), metal nitride (MN), metal boride (MB), metal oxycarbide (MCO), metal oxynitride (MNO), metal oxyboride (MOB), metal carbonitride (MCN), metal carboboride, metal boronitride (MBN), metal oxycarbonitride (MCON), metal oxyboronitride (MBON), metal oxyborocarbide (MBOC) or metal oxyborocarbonitride. The metal films are made up of the components named in any suitable amount, either stoichiometrically or non-stoichiometrically. A film that consists essentially of the named component has greater than or equal to about 95, 96, 97, 98 or 99 percent of the named components on an atomic basis.

In some embodiments, the film formed is a doped metal oxide film in which dopant elements are added (e.g., B, P, As). Doping of the film can be done at the same time as film formation by, for example, addition of a dopant precursor, or separately by, for example, ion implantation.

The metal film can be deposited by a CVD process in which the metal precursor and the co-reactant are mixed prior to or at the time of exposure to the substrate surface. Mixing the metal precursor and the co-reactant may allow gas phase reactions which can deposit on the substrate surface.

In some embodiments, the metal film is deposited by an ALD process in which the metal-precursor and co-reactant are exposed to the substrate surface separately and sequentially so that the metal precursor and co-reactant do not mix. For example, in a time-domain ALD process, the entire substrate surface is exposed to the metal precursor and then the co-reactant with a purge step between to prevent gas phase mixing. Only one of the metal precursor and the co-reactant are flowed into the processing chamber at a time in the time-domain ALD process.

In a spatial ALD process, the metal precursor and the co-reactant are flowed into different portions of the processing chamber and separated by, for example, a gas curtain or physical barrier to prevent gas phase mixing and reaction. In spatial ALD, a portion of the substrate surface may be exposed to the metal precursor and a separate portion of the substrate surface may be exposed to the co-reactant at the same time while separating of the gases is maintained.

Some embodiments of the disclosure are directed to methods of depositing a film doped with a lanthanide. A metal or dielectric film can be deposited by a suitable CVD or ALD process and lanthanide species can be doped into the film by using the bis-amidinate precursor. The bis-amidinate precursor can be metered into another metal precursor in an amount suitable to form a dopant. In some embodiments, the metal film can be deposited by ALD and some of the ALD cycles include the bis-amidinate precursor.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A processing method comprising exposing a substrate surface to a bis-amidinate metal precursor and a co-reactant to form a metal containing film, the bis-amidinate metal precursor comprising a metal atom comprising one or more lanthanide, two amidinate ligands and one or more non-amidinate ligand.

2. The processing method of claim 1, wherein the lanthanide is one or more of La, Ce, Pr, Nd, Pm, Sm, Eu, Gd, Tb, Dy, Ho, Er, Tm, Yb, Lu, Y or Sc.

3. The processing method of claim 1, wherein the one or more non-amidinate ligand comprise neutral ligands.

4. The processing method of claim 1, wherein the non-amidinate ligands comprise one or more of an allyl ligand, cyclopentadiene or substituted cyclopenadiene.

5. The processing method of claim 1, wherein one or more of the two amidinate ligands is a substituted amidinate ligand.

6. The processing method of claim 5, wherein the substituted amidinate ligand has a C₁₋₈ alkyl, C₁₋₈ alkenyl, C₁₋₈ alkynyl, branched alkyl or cycloalkyl group.

7. The processing method of claim 1, wherein the non-amidinate ligand of the metal precursor comprises NR₂, where each R is independently a hydrogen, an alkyl, alkenyl, alkynyl or cycloalkyl group.

8. The processing method of claim 7, wherein each R has less than or equal to 8 carbons.

9. The processing method of claim 1, wherein the non-amidinate ligand comprises an N—N—N group.

10. The processing method of claim 1, wherein the non-amidinate ligand coordinates to the metal atom through one or more nitrogen atoms so that the bis-amidinate metal precursor has only nitrogen bonding to the metal atom.

11. The processing method of claim 1, wherein the non-amidinate ligand comprises pyridine.

12. The processing method of claim 1, wherein each of the amidinate ligands has the general formula RNCR′NR″, where each R, R′ and R″ is independently H, a C₁₋₆ alkyl or SiMe₃.

13. The processing method of claim 1, wherein the co-reactant comprises one or more of H₂O, O₂, O₃, O plasma, H₂O₂, NO or NO₂ and the metal containing film comprises a metal oxide.

14. The processing methods of claim 1, wherein the co-reactant comprises one or more of NO, NO₂, NH₃, N₂H₂ or plasma thereof and the metal containing film comprises a metal nitride.

15. The processing method of claim 1, wherein the co-reactant comprises an organic species and the film comprises a metal carbide.

16. The processing method of claim 1, wherein the metal containing film comprises one or more of a metal carbide, metal oxide, metal nitride, metal oxycarbide, metal oxynitride, metal carbonitride or metal oxycarbonitride film.

17. The processing method of claim 1, wherein the bis-amidinate metal precursor and the co-reactant are exposed to the substrate surface in a mixture.

18. The processing method of claim 1, wherein the bis-amidinate metal precursor and the co-reactant are exposed to the substrate surface sequentially so that the metal precursor and co-reactant do not mix.

19. A processing method comprising exposing a substrate surface to a bis-amidinate metal precursor and a co-reactant to form a metal containing film, the bis-amidinate metal precursor comprising a compound with the structure 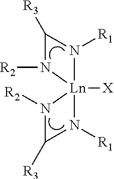
where each of R1, R2 and R3 are independently selected from hydrogen, C1-C8 alkyl, C1-C8 alkenyl, C1-C8 alkynyl, C3-C8 cycloalkyl, dimethylamine, diethylamine, bis(trimethylsilyl)amine or trimethylsilyl groups, the metal atom comprising one or more of La, Ce, Pr, Nd, Pm, Sm, Eu, Gd, Tb, Dy, Ho, Er, Tm, Yb, Lu, Y or Sc, and X is a non-amidinate ligand.

20. A processing method comprising exposing a substrate surface to a bis-amidinate metal precursor and a co-reactant to form a metal containing film, the bis-amidinate metal precursor comprising a metal atom comprising one or more of La, Ce, Pr, Nd, Pm, Sm, Eu, Gd, Tb, Dy, Ho, Er, Tm, Yb, Lu, Y or Sc, the metal precursor further comprising at least one non-amidinate ligand selected from the group consisting of cyclopentadiene, substituted cyclopenadiene, pyridine, substituted pyridine, an RN—CR—CR—NR group, an RN—CR—CR₂ group, a RN—N—NR group, a NR₂ or combinations thereof, where each R is independently H, methyl, ethyl, propyl, isopropyl, butyl, tert-butyl or trimethylsilyl.
